(19) United States
(12) Patent Application Publication
(10) Pub. No.: US 2013/0262942 A1
(43) Pub. Date: Oct. 3, 2013

(54) FLASH MEMORY LIFETIME EVALUATION METHOD

(71) Applicant: Yung-Chiang CHU, Taipei City (TW)

(72) Inventor: Yung-Chiang CHU, Taipei City (TW)

(21) Appl. No.: 13/431,336

(22) Filed: Mar. 27, 2012

(51) Int. Cl. G11C 29/10; G06F 11/263

(52) U.S. Cl. 714/718; 714/E11.177

(57) ABSTRACT

A flash memory lifetime evaluation method is introduced for dynamically amending, detecting and evaluating an ideal lifetime (or standard lifetime) of a built-in or expanded flash memory of an electronic device, and the method comprises the steps of calculating the ideal lifetime according to the capacity of the flash memory, creating a spare area in at least one of the flash memory and the control center, generating a testing command by the control center and transmitting the testing command to the flash memory such that the flash memory executes a memory test according to the testing command, and the flash memory feeds back a test result to the spare area as an amend parameter according to the memory test, and the control center retrieves the amend parameter stored in the spare area to selectively amend the ideal lifetime by the amend parameter.

### FIELD OF THE INVENTION

The present invention relates to a flash memory lifetime evaluation method, in particular to the method provided for a control center to dynamically amend, detect and evaluate an ideal lifetime of a flash memory in an electronic device.

### BACKGROUND OF THE INVENTION

At present, NAND flash memory is used extensively in various electronic products such as a tablet PC, a Smartphone, a desktop computer, and a notebook computer, and the flash memory in the electronic products also serves as a storage area for storing system boot codes such as an embedded multi media card (eMMC) or an integrated solid state drive (iSSD), in addition to its a role of storing data.

The flash memory uses the structure of a floating gate to latch electric charges to achieve the effect of storing data. In general, the flash memory can execute related commands including Erase, Write, and Read according to a command given by a control chip, and the flash memory uses a high-voltage impact method to change the storage state of data in the floating gate.

A multi-level cell (MLC) flash memory with a storage capacity of 4 GB is used as an example for illustration, wherein the multi-level cell flash memory can be operated for approximately 3,000 times under a normal memory operation (including the operation of erasing, writing or reading data of the memory). If a wear leveling technology is incorporated, the total using capacity of the flash memory is approximately equal to 12,000 GB (4 GB*3,000). If a capacity of 1 G is used daily, the flash memory can be used for 12,000 days (12,000G/1 G), and there are 365 days a year, so that the flash memory can be used for 32.87 years (12,000 days/365 days/year), and the lifetime of 32.87 years is defined as an ideal lifetime of the flash memory.

In the natural environment, the flash memory will be declined slowly by itself, even if the flash memory is not used at all.

Although the flash memory has the advantages of low cost, low power consumption and low read delay, yet the structure and operation method of the flash memory cause a risk on the use of the flash memory having a limited number of times of reading and writing data. The aforementioned estimations are made under the most favorable conditions, and actually, the flash memory may be affected by different conditions including a user's habit of using the flash memory or a change of environments, such that the actual lifetime of the flash memory is very different from the ideal lifetime.

Therefore, the present invention provides a method of predicting the lifetime of the flash memory accurately to overcome the drawback of the prior art that cannot predict the lifetime of the flash memory accurately.

### SUMMARY OF THE INVENTION

Therefore, it is a primary objective of the present invention to provide a flash memory lifetime evaluation method used for dynamically amending, detecting and evaluating an ideal lifetime of a built-in or expanded flash memory in an electronic device to accurately amend the ideal lifetime, so as to estimate an actual lifetime of the flash memory accurately.

To achieve the aforementioned and other objectives, the present invention provides a flash memory lifetime evaluation method for a control center to dynamically amend, detect and evaluate an ideal lifetime of a built-in or extended flash memory of an electronic device, and the method comprises the steps of: detecting a capacity of a memory block, a memory page and a memory cell in the flash memory, and calculating the ideal lifetime of the flash memory by a structure type of the flash memory; creating a spare area in at least one of the flash memory and the control center; generating a testing command by the control center and transmitting the testing command to the flash memory, such that the flash memory executes a memory test according to the testing command, and the flash memory feeds back a test result to the spare area according to the memory test and uses the test result as an amend parameter; and the control center retrieves the amend parameter in the spare area to selectively amend the ideal lifetime by the amend parameter.

Compared with the prior art, the flash memory lifetime evaluation method of the present invention can issue an erase command or a program command (including a write command or a read command for changing the data stored in a floating gate in the flash memory by the flash memory through a high-voltage impact method) in a control center (such as a control driver or a remote monitoring server), and related error correction code (ECC) bits or electric property parameters can be retrieved from the flash memory and used as a basis for amending the ideal lifetime.

In addition, the parameters are stored in a memory block, a memory page and a spare area specified by the memory cell or the remote monitoring server of the flash memory, such that the amending method of the ideal lifetime can be used to predict the actual lifetime of the flash memory accurately by retrieving the parameters.

### BRIEF DESCRIPTION OF THE DRAWINGS

FIG. 1 is a flow chart of a flash memory lifetime evaluation method in accordance with a preferred embodiment of the present invention; and

FIGS. 2 to 10 are flow charts of producing amend parameters of FIG. 1.

### DETAILED DESCRIPTION OF THE PREFERRED EMBODIMENTS

The objects, characteristics and effects of the present invention will become apparent with the detailed description of the preferred embodiments and the illustration of related drawings as follows.

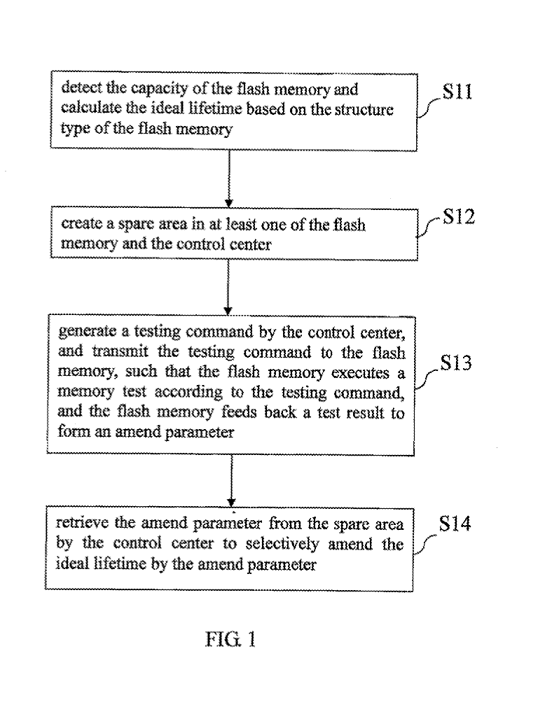

With reference to FIG. 1 for a flow chart of a flash memory lifetime evaluation method in accordance with a preferred embodiment of the present invention, the flash memory lifetime evaluation method is provided for a control center to dynamically amend, detect and evaluate an ideal lifetime of a built-in or expanded flash memory of an electronic device. Wherein, the control center refers to a driver for driving the flash memory or a remote monitoring server connected to the electronic device via the Internet for controlling the flash memory.

The flash memory lifetime evaluation method comprises the following steps:

S11: Detect the capacity of the flash memory having a memory block, a memory page and a memory cell, and calculate the ideal lifetime based on the structure type of the flash memory. Wherein, the structure type of the flash memory is a single-level cell (SLC) or multi-level cell (MLC) NOR or NAND flash memory. In this step, the capacity of the flash memory and the structure type are used to estimate the ideal lifetime. For example, a multi-level cell flash memory with a capacity of 4 GB has an ideal lifetime of 32.87 years.

S12: Create a spare area in at least one of the flash memory and the control center. Wherein, the spare area is a storage space provided for storing the amend parameter.

S13: Generate a testing command by the control center, and transmit the testing command to the flash memory, such that the flash memory executes a memory test according to the testing command, and the flash memory feeds back a test result to form an amend parameter and stores the amend parameter into the spare area. In this step, the control center generates the testing command to the flash memory, such that the flash memory can execute the memory test to produce a test result according to the testing command, and the test result is the amend parameter used for amending the ideal lifetime. Wherein sources for producing the amend parameter are listed below:

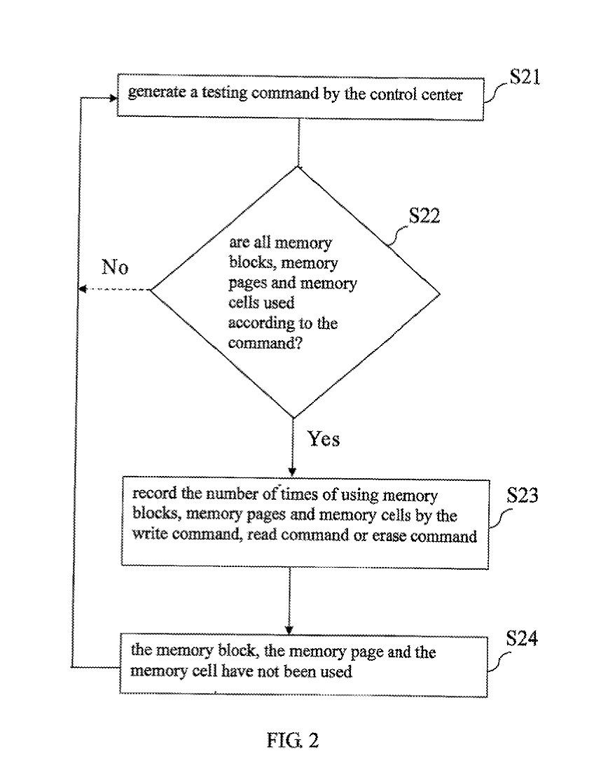

(1) The amend parameter records the number of times of executing the read command, write command and erase command in each memory block, memory page and memory cell of the flash memory separately. Refer to FIG. 2 for the procedure of retrieving the amend parameter. In FIG. 2, the procedure starts from Step S21.

S21: Generate a testing command by the control center.

S22: Determine by the flash memory whether all of the memory blocks, the memory pages and the memory cells are used according to the testing command.

S23: Determine whether the testing command is a write command, a read command or an erase command, and record the number of times of using the write command, read command or erase command in each of the memory blocks, memory pages and the memory cells respectively.

S24: Return to the step S21 to record the number of times of use, if the memory block, the memory page and the memory cell have not been used.

In other words, if the control center generates a command for recording the number of times of using the flash memory, the flash memory will execute a command such as the erase command, write command and read command to each of the memory blocks, the memory pages and the memory cells and record the number of times of using each of the memory blocks, the memory pages and the memory cells, wherein the number of times of use is recorded in the spare area.

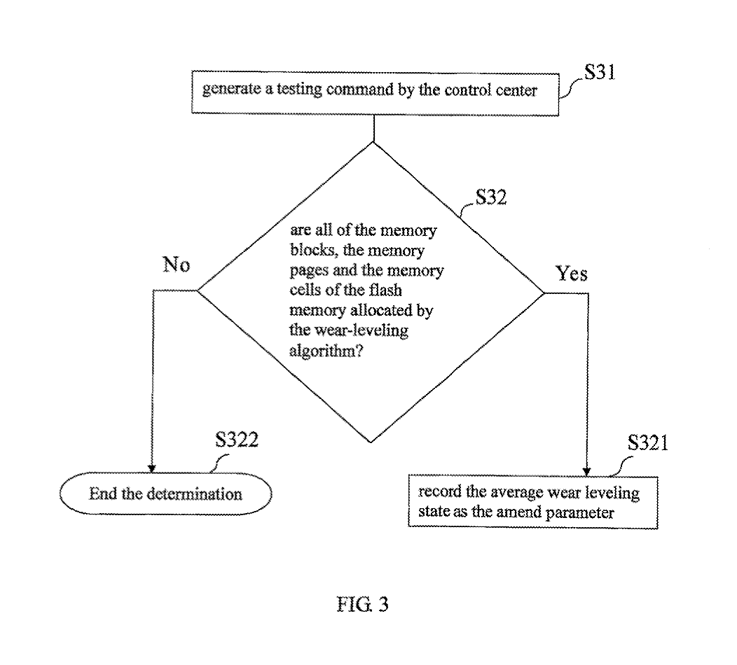

(2) The amend parameter records an average wear state of the memory block, the memory page and the memory cell in the flash memory based on a wear-leveling algorithm. Refer to FIG. 3 for the procedure of retrieving the amend parameter. In FIG. 3, the procedure starts from the step S31.

S31: Generate a testing command by the control center.

S32: Determine by the flash memory whether all of the memory blocks, the memory pages and the memory cells are allocated by the wear-leveling algorithm. If yes, then execute the step S321, or else execute the step S322.

S321: Record the average wear leveling state as the amend parameter.

S322: End the determination.

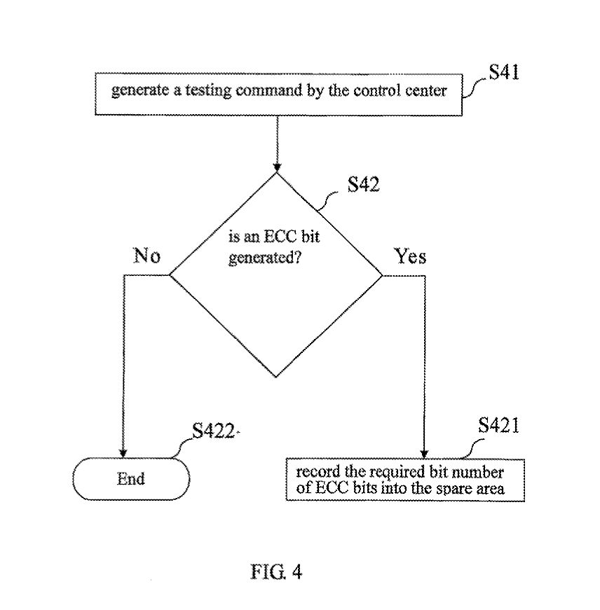

(3) The amend parameter records the correction bits of the flash memory fed back from an error correction code engine to the flash memory. Refer to FIG. 4 for the procedure of retrieving the amend parameter. In FIG. 4, the procedure starts from the Step 41.

S41: Generate a testing command by the control center, such that the ready/busy pin in the flash memory is changed from a low potential to a high potential according to the testing command.

S42: Confirm whether an error correction code (ECC) bit is generated. If yes, then execute the step S421, or else execute the step S422.

S421: Record the required bit number of ECC bits into the spare area.

S422: End the determination.

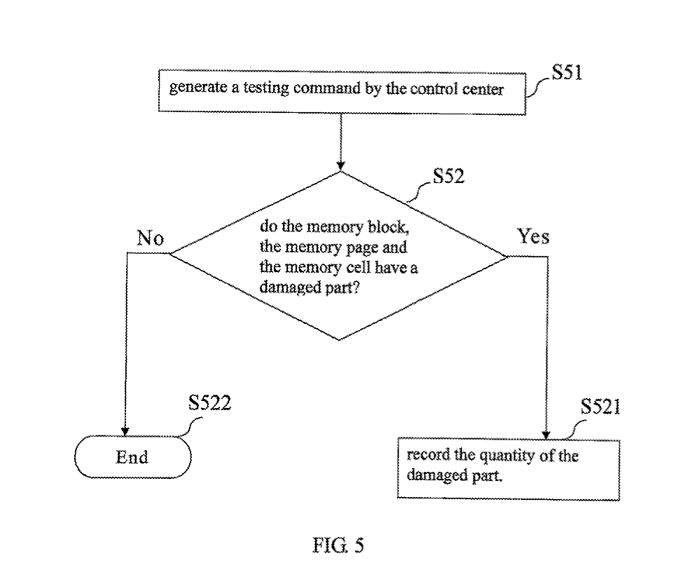

(4) The amend parameter records the number of detected damaged memory blocks, memory pages and memory cells in the flash memory after the testing command is executed. Refer to FIG. 5 for the procedure of retrieving the amend parameter. In FIG. 5, the procedure starts from the Step 51.

S51: Generate a testing command (such as an erase command) by the control center, such that the memory block, the memory page and the memory cell are all in the state of 0xFF or 0x00.

S52: Determine whether the memory block, the memory page and the memory cell have a damaged part. If yes, then execute the step S521, or else execute the step S522.

S521: Record the quantity of the damaged part.

S522: End the determination.

In another preferred embodiment, after the steps S51˜S52 are executed, a step S53 can be executed after the step S521 takes place. The step S53 continuously executes a testing command in the flash memory, and compares an increased number of damaged memory blocks, memory pages and memory cells and a damage speed between the previous time and the next time.

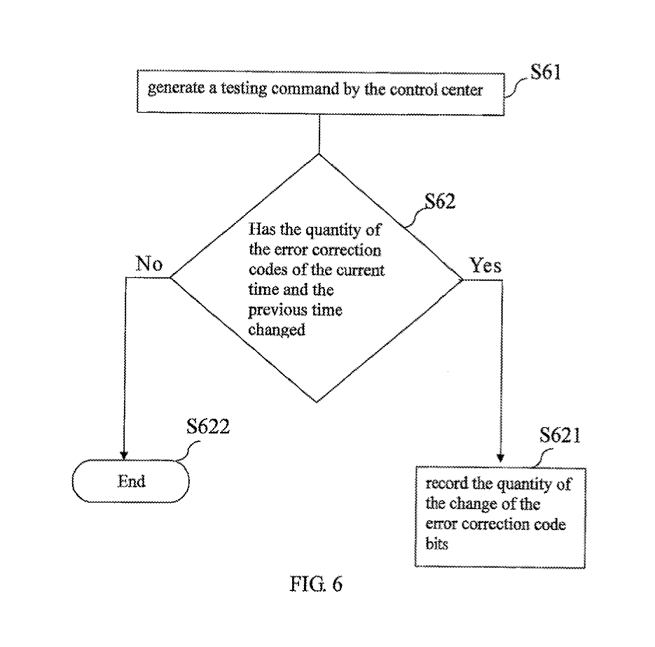

(5) After the read command has been executed for a plurality of times in specific memory block, memory page and memory cell of the flash memory, the amend parameter, the number of error correction code bits in the memory block, the memory page and the memory cell with an unstable changing state is recorded. Refer to FIG. 6 for the procedure of retrieving the amend parameter. In FIG. 6, the procedure starts from the Step 61.

S61: Generate a testing command (such as a read command) by the control center.

S62: Determine whether the quantity of the error correction codes of the current time and the previous time has changed. If yes, then execute the step S621, or else execute the step S622.

S621: Record the quantity of the change of the error correction code bits.

S622: End the determination.

(6) After the amend parameter is an unstable state of the test result fed back by the flash memory, a read command, a write command and an erase command after the electronic device execute in the flash memory.

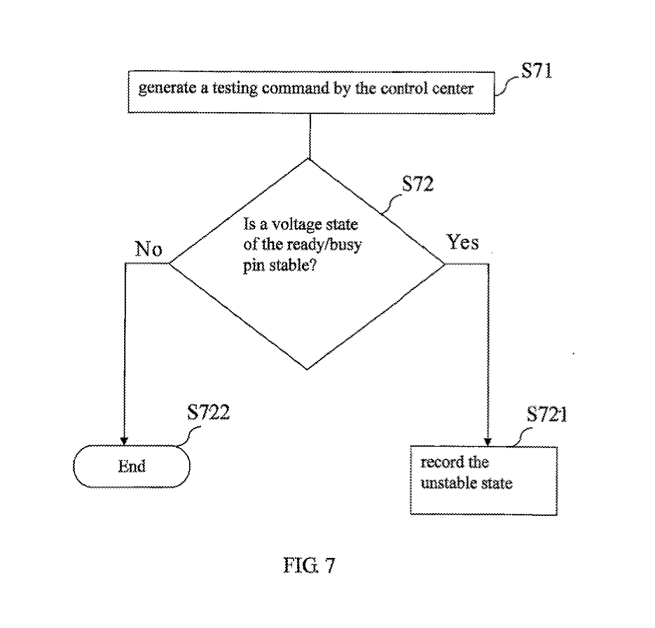

Refer to FIG. 7 for the procedure of retrieving the amend parameter. In FIG. 7, the procedure starts from the Step 71.

S71: Generate a testing command by the control center to retrieve a state such as the state of a ready/busy pin in the flash memory.

S72: Determine whether a voltage state of the ready/busy pin is stable. If no, (such as the voltage is constantly situated at a fixed potential either a high potential or a low potential), then execute the step S721, or else execute the step S722.

S721: Record the unstable state.

S722: End the determination.

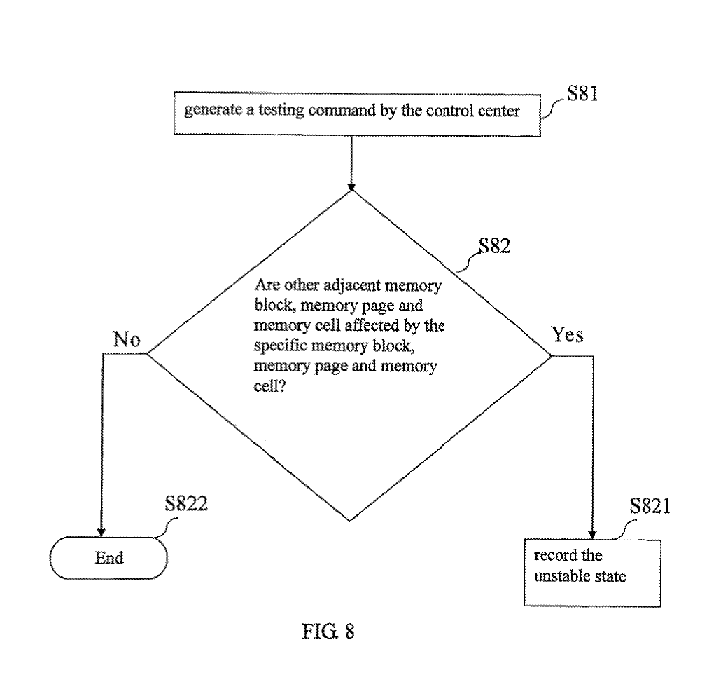

(7) The amend parameter is a correction state of other recorded and monitored memory block, memory page and memory cell adjacent to specific memory block, memory page and memory cell, after the read command is executed for a plurality of times for the specific memory block, memory page and memory cell of the flash memory. Refer to FIG. 8 for the procedure of retrieving the amend parameter. In FIG. 8, the procedure starts from the Step 81.

S81: Generate a testing command by the control center to monitor the correction state of other memory block, memory page and memory cell adjacent to specific memory block, the memory page and memory cell.

S82: Determine whether other adjacent memory block, memory page and memory cell are affected by the specific memory block, memory page and memory cell. If yes, then execute the step S821, or else execute the step S822.

S821: Record the unstable state.

S822: End the determination.

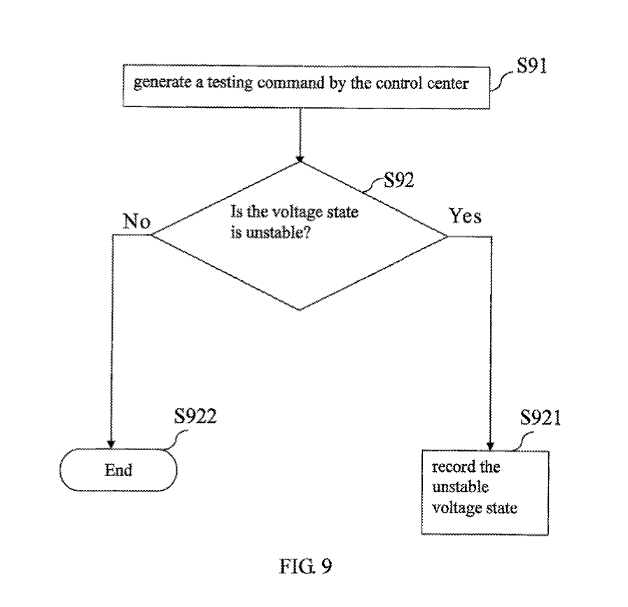

(8) The amend parameter is a recorded abnormal voltage state of a pin in the flash memory, after the electronic device executes the read command, write command and erase command in the flash memory. Refer to FIG. 9 for the procedure of retrieving the amend parameter. In FIG. 9, the procedure starts from the Step 91.

S91: Generate a testing command by the control center to monitor a voltage state of the specific memory block, memory page and memory cell.

S92: Determine whether the voltage state is unstable. If yes, then execute the step S921, or else execute the step S922.

S921: Record the unstable voltage state.

S922: End the determination.

(9) The amend parameter is a recorded state of a chip enable pin (CE pin) in the flash memory failing to execute an erase of a chip having the memory block, the memory page and the memory cell according to the erase command, after the flash memory executes the erase command.

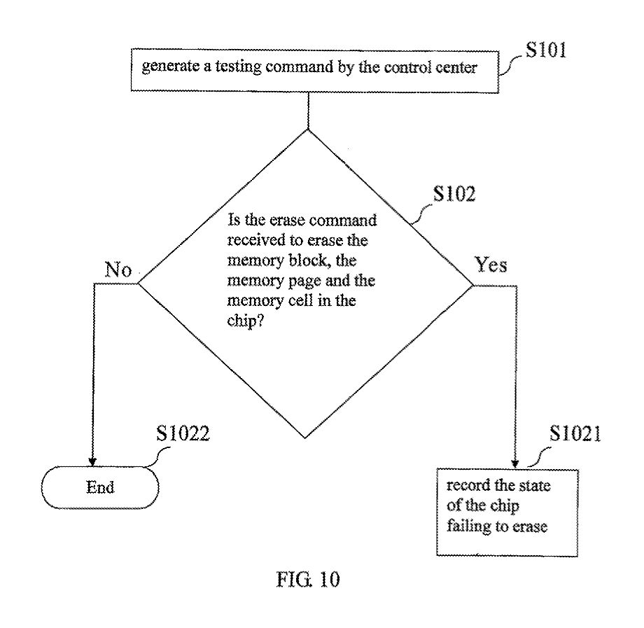

Refer to FIG. 10 for the procedure of retrieving the amend parameter. In FIG. 10, the procedure starts from the Step 101.

S101: Generate a testing command by the control center to execute an erase command of a chip having the memory block, the memory page and the memory cell.

S102: Determine whether the erase command is received to erase the memory block, the memory page and the memory cell in the chip. If yes, then execute S1021, or else execute the step S1022.

S1021: Record the state of the chip failing to erase.

S1022: End the determination.

S14: Retrieve the amend parameter from the spare area by the control center to selectively amend the ideal lifetime by the amend parameter.

Therefore, after the flash memory lifetime evaluation method of the present invention issues an erase command or program command (such as a write command or a read command to change the electrically charged data stored in a floating gate of the flash memory by the high-voltage impact method) to the flash memory by the control center (such as a control driver or a remote monitoring server), the related error correction code (ECC) bits or electric property parameters are obtained and used as a basis for amending the ideal lifetime.

In addition, the parameters can be stored in a spare area specified by the memory block, the memory page and the memory cell in the flash memory or the remote monitoring server, such that the ideal lifetime can be amended by the parameters and used to predict the actual lifetime of the flash memory.

While the invention has been described by means of specific embodiments, numerous modifications and variations could be made thereto by those skilled in the art without departing from the scope and spirit of the invention set forth in the claims.

What is claimed is:

1. A flash memory lifetime evaluation method, provided for a control center to dynamically amend, detect and evaluate an ideal lifetime of a built-in or extended flash memory of an electronic device, and the method comprising the steps of:
detecting a capacity of a memory block, a memory page and a memory cell in the flash memory, and calculating the ideal lifetime of the flash memory by a structure type of the flash memory;
creating a spare area in at least one of the flash memory and the control center;
generating a testing command by the control center and transmitting the testing command to the flash memory, such that the flash memory executes a memory test according to the testing command, and the flash memory feeds back a test result to the spare area according to the memory test to form an amend parameter; and
retrieving the amend parameter in the spare area by the control center, to selectively amend the ideal lifetime by the amend parameter.

2. The flash memory lifetime evaluation method of claim 1, wherein the ideal lifetime is amended by a product of the amend parameter and the ideal lifetime.

3. The flash memory lifetime evaluation method of claim 1, wherein the amend parameter is a recorded number of times of executing a read command, a write command and an erase command in each of the memory block, the memory page and the memory cell of the flash memory separately.

4. The flash memory lifetime evaluation method of claim 1, wherein the amend parameter is an average wear state of the memory block, the memory page and the memory cell in the flash memory recorded according to a wear-leveling algorithm.

5. The flash memory lifetime evaluation method of claim 1, wherein the amend parameter is a recorded error correction code bit fed back by an error correction code engine to the flash memory for performing a correction.

6. The flash memory lifetime evaluation method of claim 5, wherein the amend parameter further includes a voltage state of a ready/busy pin (R/B pin) in the flash memory detected to determine whether the voltage state is constantly maintained at a fixed electric potential before the error correction code engine reports the error correction code bit of the flash memory.

7. The flash memory lifetime evaluation method of claim 1, wherein the amend parameter is a recorded number of detected damaged memory blocks, memory pages and memory damages after the testing command is executed in the flash memory.

8. The flash memory lifetime evaluation method of claim 7, further comprising the steps of executing the testing command in the flash memory continuously to compare an increased number of damaged memory blocks, memory pages and memory cells and a damage speed between the previous time and the next time.

9. The flash memory lifetime evaluation method of claim 1, wherein the amend parameter is a recorded number of bits of the error correction code bit in specific memory blocks, memory pages and memory cells that produce an unstable change state, after the read command is executed for a plurality of times for the specific memory block, memory page and memory cell of the flash memory.

10. The flash memory lifetime evaluation method of claim 1, wherein the amend parameter is a correction state of other recorded and monitored memory block, memory page and memory cell adjacent to specific memory block, memory page and memory cell, after the read command is executed for a plurality of times for the specific memory block, memory page and memory cell of the flash memory.

11. The flash memory lifetime evaluation method of claim 1, wherein the amend parameter is a recorded unable state of the test result fed back by the flash memory after the electronic device executes the read command, write command and erase command in the flash memory.

12. The flash memory lifetime evaluation method of claim 1, wherein the amend parameter is a recorded abnormal voltage state of a pin in the flash memory, after the electronic device executes the read command, write command and erase command in the flash memory.

13. The flash memory lifetime evaluation method of claim 1, wherein the amend parameter is a recorded unstable voltage change sate of specific memory block, memory page and memory cell when the flash memory operates the specific memory block, memory page and the memory cell.

14. The flash memory lifetime evaluation method of claim 1, wherein the amend parameter is a recorded state of a chip enable pin in the flash memory failing to execute an erase of a chip having the memory block, the memory page and the memory cell according to the erase command, after the flash memory executes the erase command.

15. The flash memory lifetime evaluation method of claim 1, wherein the control center is a control driver or a remote monitoring server that controls the flash memory.

16. The flash memory lifetime evaluation method of claim 15, wherein the control center dynamically amend, detect and evaluate the ideal lifetime of a built-in or expanded flash memory of the electronic device via the Internet.

17. The flash memory lifetime evaluation method of claim 1, wherein the structure type flash memory is a single-level cell or multi-level cell NOR or NAND flash memory.
